(19) United States
(12) Patent Application Publication
(10) Pub. No.: US 2026/0045420 A1
(43) Pub. Date: Feb. 12, 2026

(54) VARIABLE CAPACITOR, IMPEDANCE MATCHING APPARATUS, AND PLASMA PROCESSING APPARATUS

(71) Applicant: Tokyo Electron Limited, Tokyo (JP)

(72) Inventors: Masato MORISHIMA, Tokyo (JP); Shinichi TANABE, Tokyo (JP)

(73) Assignee: Tokyo Electron Limited, Tokyo (JP)

(21) Appl. No.: 19/366,589

(22) Filed: Oct. 23, 2025

Related U.S. Application Data
(63) Continuation of application No. PCT/JP2024/016181, filed on Apr. 25, 2024.

(30) Foreign Application Priority Data
May 9, 2023 (JP) 2023-077313

(51) Int. Cl. H01G 7/00; H01G 2/10; H01J 37/32

(52) U.S. Cl. CPC H01G 7/00; H01G 2/10; H01J 37/32183; H01J 37/32926; H01J 2237/334

(57) ABSTRACT

A variable capacitor includes a holder, at least one first electrode, and at least two second electrodes. The holder holds an ionic liquid, the at least one first electrode is provided in the holder, and receives either a positive or negative direct-current voltage and the at least two second electrodes are provided on portions of the holder where electric double layers in the ionic liquid are formed when the direct-current voltage is applied to the first electrode, and the at least two second electrodes supply a radio-frequency power via the holder.

### CROSS-REFERENCE TO RELATED APPLICATIONS

This application is a bypass continuation application of international application No. PCT/JP2024/016181 having an international filing date of Apr. 25, 2024, and designating the United States, the international application being based upon and claiming the benefit of priority from Japanese Patent Application No. 2023-077313, filed on May 9, 2023, the entire contents of each are incorporated herein by reference.

### TECHNICAL FIELD

The present disclosure relates to a variable capacitor, an impedance matching apparatus, and a plasma processing apparatus.

### BACKGROUND

PTL 1 below discloses “a phased-switched tunable impedance network having an input configured to be coupled to a source and having an output configured to be coupled to a load, the tunable impedance network including: one or more phase-switched capacitor circuits, each of the one or more phase-switched capacitor circuits including a first terminal and a second terminal, at least one switch having a first terminal coupled to the first terminal of the phase-switched capacitor circuit and a second terminal coupled to the second terminal of the phase-switched capacitor circuit, and at least one capacitive element coupled in parallel to the switch, the switch switching a capacitance into the phase-switched capacitor circuit in response to the switch being biased to a non-conductive state, and the switch excluding the capacitance from the phase-switched capacitor circuit in response to the switch being biased to a conductive state; and a controller configured to supply respective control signals to the one or more phase-switched capacitor circuits, each of the phase-switched capacitor circuits supplying a corresponding selected capacitance value in response to the supplied control signal, and each of the control signals performing zero voltage switching (ZVS) by biasing at least one switch of the phase-switched capacitor circuit to the conductive state when a voltage of the at least one capacitive element of the phase-switched capacitor circuit returns to zero”.

### CITATION LIST

### Patent Documents

PTL 1: JP6685305B

### SUMMARY

The disclosure provides a technique capable of continuously and quickly controlling an electrostatic capacitance.

A variable capacitor according to an aspect of the disclosure includes a holder, a first electrode, and a second electrode. The holder is configured to hold an ionic liquid. At least one first electrode is provided in the holder, and is configured to receive either a positive or negative direct-current voltage. At least two second electrodes are provided on portions of the holder where electric double layers in the ionic liquid are formed when the direct-current voltage is applied to the first electrode, and are configured to supply a radio-frequency power via the holder.

According to the disclosure, the electrostatic capacitance can be continuously and quickly controlled.

### BRIEF DESCRIPTION OF DRAWINGS

FIG. 1 is a schematic cross-sectional view illustrating an example of a plasma processing apparatus according to one or more embodiments of the disclosure.

FIG. 2 is a schematic diagram illustrating an example of a second impedance matching circuit according to one or more embodiments.

FIG. 3 is a diagram illustrating plasma processing of the plasma processing apparatus according to one or more embodiments.

FIG. 4 is a diagram schematically illustrating an example of a configuration of a variable capacitor according to one or more embodiments.

FIG. 5A is a diagram illustrating a specific example of the configuration of the variable capacitor according to one or more embodiments.

FIG. 5B is a diagram illustrating a specific example of the configuration of the variable capacitor according to one or more embodiments.

### DETAILED DESCRIPTION

Hereinafter, an embodiment of a variable capacitor, an impedance matching apparatus, and a plasma processing apparatus disclosed in the present application will be described in detail with reference to the drawings. The variable capacitor, the impedance matching apparatus, and the plasma processing apparatus disclosed are not limited to one or more embodiments.

The plasma processing apparatus that generates plasma in a chamber and performs plasma processing is known. The plasma processing apparatus supplies a radio-frequency power from a radio-frequency power supply to an electrode provided in the chamber so as to generate the plasma in the chamber. In order to efficiently supply the radio-frequency power to the electrode in the chamber, the impedance matching apparatus is provided between the radio-frequency power supply and the electrode. The impedance matching apparatus includes the variable capacitor. The impedance matching apparatus matches an impedance by controlling an electrostatic capacitance of the variable capacitor. In order to improve a matching speed of the impedance matching apparatus, the variable capacitor capable of continuously and quickly controlling the electrostatic capacitance is required.

### Embodiment

### [Configuration of Plasma Processing Apparatus]

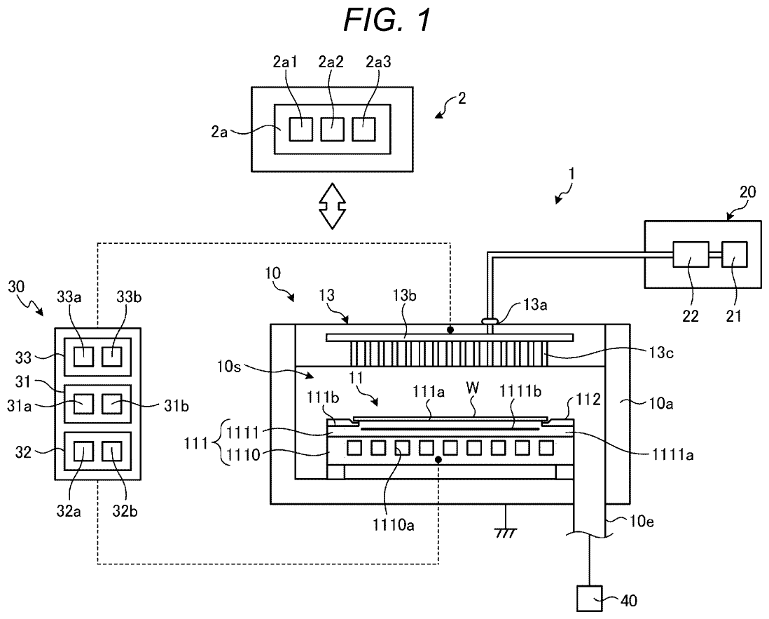

Hereinafter, a configuration example of a plasma processing apparatus 1 according to one or more embodiments will be described. FIG. 1 is a schematic cross-sectional view illustrating an example of the plasma processing apparatus 1 according to one or more embodiments of the disclosure.

The plasma processing apparatus 1 according to one or more embodiments is implemented by a capacitively-coupled plasma processing apparatus. The plasma processing apparatus 1 includes a plasma processing chamber 10, a gas supply 20, a power supply 30, and an exhaust system 40. Further, the plasma processing apparatus 1 includes a substrate support 11 and a gas introduction unit. The gas introduction unit is configured to introduce at least one processing gas into the plasma processing chamber 10. The gas introduction unit includes a shower head 13. The substrate support 11 is disposed in the plasma processing chamber 10. The shower head 13 is disposed above the substrate support 11. In one or more embodiments, the shower head 13 constitutes at least a portion of a ceiling of the plasma processing chamber 10. The plasma processing chamber 10 has a plasma processing space 10s defined by the shower head 13, a sidewall 10a of the plasma processing chamber 10, and the substrate support 11. The plasma processing chamber 10 has at least one gas supply port for supplying at least one processing gas into the plasma processing space 10s, and at least one gas exhaust port for exhausting the gas from the plasma processing space. The plasma processing chamber 10 is grounded. The shower head 13 and the substrate support 11 are electrically insulated from a housing of the plasma processing chamber 10.

The substrate support 11 includes a main body 111 and a ring assembly 112. The main body 111 has a central region 111a, which supports a substrate W, and an annular region 111b, which supports the ring assembly 112. A wafer is an example of the substrate W. The annular region 111b of the main body 111 surrounds the central region 111a of the main body 111 in a plan view. The substrate W is disposed on the central region 111a of the main body 111, and the ring assembly 112 is disposed on the annular region 111b of the main body 111 so as to surround the substrate W on the central region 111a of the main body 111. Accordingly, the central region 111a is also referred to as a substrate support surface for supporting the substrate W, and the annular region 111b is also referred to as a ring support surface for supporting the ring assembly 112.

In one or more embodiments, the main body 111 includes a base 1110 and an electrostatic chuck 1111. The base 1110 includes a conductive member. The conductive member of the base 1110 may function as a lower electrode. The electrostatic chuck 1111 is disposed on the base 1110. The electrostatic chuck 1111 includes a ceramic member 1111a, and an electrostatic electrode 1111b disposed in the ceramic member 1111a. The ceramic member 1111a has the central region 111a. In one or more embodiments, the ceramic member 1111a also has the annular region 111b. Another member that surrounds the electrostatic chuck 1111, such as an annular electrostatic chuck and an annular insulating member, may have the annular region 111b. In this case, the ring assembly 112 may be disposed on the annular electrostatic chuck or the annular insulating member, or may be disposed on both the electrostatic chuck 1111 and the annular insulating member. Further, at least one RF/DC electrode coupled to a radio frequency (RF) power supply 31 and/or a direct current (DC) power supply 32 to be described below may be disposed inside the ceramic member 1111a. In this case, at least one RF/DC electrode functions as the lower electrode. When a bias RF signal and/or DC signal, which will be described later, are supplied to the at least one RF/DC electrode, the RF/DC electrode is also called a bias electrode. The conductive member of the base 1110 and at least one RF/DC electrode may function as a plurality of lower electrodes. The electrostatic electrode 1111b may instead function as the lower electrode. Accordingly, the substrate support 11 includes at least one lower electrode.

The ring assembly 112 includes one or more annular members. In one or more embodiments, the one or more annular members include one or more edge rings and at least one cover ring. The edge ring is formed of a conductive material or an insulating material, and the cover ring is formed of an insulating material.

Further, the substrate support 11 may include a temperature control module configured to adjust at least one of the electrostatic chuck 1111, the ring assembly 112, and the substrate W to a target temperature. The temperature control module may include a heater, a heat transfer medium, a flow path 1110a, or a combination thereof. A heat transfer fluid, such as brine or gas, flows through the flow path 1110a. In one or more embodiments, the flow path 1110a is formed in the base 1110, and one or more heaters are disposed in the ceramic member 1111a of the electrostatic chuck 1111. Further, the substrate support 11 may include a heat transfer gas supply configured to supply a heat transfer gas to a gap between a rear surface of the substrate W and the central region 111a.

The shower head 13 is configured to introduce at least one processing gas from the gas supply 20 into the plasma processing space 10s. The shower head 13 has at least one gas supply port 13a, at least one gas diffusion chamber 13b, and a plurality of gas introduction ports 13c. The processing gas supplied to the gas supply port 13a passes through the gas diffusion chamber 13b and is introduced into the plasma processing space 10s from the gas introduction ports 13c. The shower head 13 further includes at least one upper electrode. The gas introduction unit may include, in addition to the shower head 13, one or a plurality of side gas injectors (SGI) that are attached to one or a plurality of openings formed in the sidewall 10a.

The gas supply 20 may include at least one gas source 21 and at least one flow rate controller 22. In one or more embodiments, the gas supply 20 is configured to supply at least one processing gas from the respective corresponding gas sources 21 to the shower head 13 via the respective corresponding flow rate controllers 22. Each flow rate controller 22 may include, for example, a mass flow controller or a pressure-controlled flow rate controller. Further, the gas supply 20 may include one or more flow rate modulation devices that modulate or pulse flow rates of at least one processing gas.

The power supply 30 includes a RF power supply 31 and an impedance matching circuit 33. The RF power supply 31 is coupled to the plasma processing chamber 10 via the impedance matching circuit 33. The RF power supply 31 is configured to supply at least one RF signal (RF power) to at least one lower electrode and/or at least one upper electrode in the plasma processing chamber 10 via the impedance matching circuit 33. Accordingly, the plasma is formed from at least one processing gas supplied into the plasma processing space 10s. Accordingly, the RF power supply 31 may function as at least a portion of a plasma generator configured to generate a plasma from one or more processing gases in the plasma processing chamber 10. Further, supplying the bias RF signal to at least one lower electrode can generate a bias potential in the substrate W to attract an ionic component in the formed plasma to the substrate W.

In one or more embodiments, the RF power supply 31 includes a first RF generator 31a and a second RF generator 31b. The impedance matching circuit 33 includes a first impedance matching circuit 33a and a second impedance matching circuit 33b. In one or more embodiments, the first RF generator 31a and the second RF generator 31b correspond to the radio-frequency power supply of the disclosure, and the first impedance matching circuit 33a and the second impedance matching circuit 33b correspond to the impedance matching apparatus of the disclosure.

The first RF generator 31a is coupled to at least one lower electrode and/or at least one upper electrode via the first impedance matching circuit 33a, and is configured to generate a source RF signal (source RF power) for generating plasma. The first impedance matching circuit 33a is electrically connected to the first RF generator 31a. In one or more embodiments, the source RF signal has a frequency within a range from 10 MHz to 150 MHz. In one or more embodiments, the first RF generator 31a may be configured to generate a plurality of source RF signals having different frequencies. The generated one or more source RF signals are supplied to at least one lower electrode and/or at least one upper electrode.

The second RF generator 31b is coupled to at least one lower electrode via the second impedance matching circuit 33b, and is configured to generate a bias RF signal (bias RF power). The second impedance matching circuit 33b is electrically connected to the second RF generator 31b. A frequency of the bias RF signal may be the same as or different from a frequency of the source RF signal. In one or more embodiments, the bias RF signal has a frequency lower than the frequency of the source RF signal. In one or more embodiments, the bias RF signal has a frequency within a range from 100 kHz to 60 MHz. In one or more embodiments, the second RF generator 31b may be configured to generate a plurality of bias RF signals having different frequencies. The generated one or more bias RF signals are supplied to at least one lower electrode. In one or more embodiments, at least one of the source RF signal and the bias RF signal may be pulsed. That is, both the source RF signal and the bias RF signal may be pulsed, or alternatively, only one of the source RF signal and the bias RF signal may be pulsed. In one or more embodiments, the source RF signal and the bias RF signal correspond to the radio-frequency power of the disclosure.

Further, the power supply 30 may include a DC power supply 32 coupled to the plasma processing chamber 10. The DC power supply 32 includes a first DC generator 32a and a second DC generator 32b. In one or more embodiments, the first DC generator 32a is configured to be connected to at least one lower electrode to generate a first DC signal. The generated first bias DC signal is applied to at least one lower electrode. In one or more embodiments, the second DC generator 32b is configured to be connected to at least one upper electrode to generate a second DC signal. The generated second DC signal is applied to at least one upper electrode.

In one or more embodiments, at least one of the first and second DC signals may be pulsed. In this case, a sequence of voltage pulses is applied to at least one lower electrode and/or at least one upper electrode. The voltage pulses may each have a rectangular, trapezoidal, or triangular pulse waveform or a combination thereof. In one or more embodiments, a waveform generator that generates the sequence of the voltage pulses from a DC signal is connected between the first DC generator 32a and at least one lower electrode. Accordingly, the first DC generator 32a and the waveform generator form a voltage pulse generator. When the second DC generator 32b and the waveform generator form a voltage pulse generator, the voltage pulse generator is connected to at least one upper electrode. The voltage pulse may have a positive polarity or a negative polarity. The sequence of the voltage pulses may include one or more positive voltage pulses and one or more negative voltage pulses in one cycle. The first and second DC generators 32a and 32b may be provided in addition to the RF power supply 31, and the first DC generator 32a may be provided instead of the second RF generator 31b.

The exhaust system 40 may be connected to, for example, a gas exhaust port 10e disposed at a bottom portion of the plasma processing chamber 10. The exhaust system 40 may include a pressure adjusting valve and a vacuum pump. The pressure adjusting valve adjusts a pressure in the plasma processing space 10s. The vacuum pump may include a turbo molecular pump, a dry pump, or a combination thereof.

The plasma processing apparatus 1 includes a controller 2. The controller 2 processes computer-executable instructions that cause the plasma processing apparatus 1 to execute various steps described in the present disclosure. The controller 2 may be configured to control elements of the plasma processing apparatus 1 to execute the various steps described herein below. In one or more embodiments, part or all of the controller 2 may be in the plasma processing apparatus 1. The controller 2 may include a processor 2a1, a storage 2a2, and a communication interface 2a3. The controller 2 is implemented, for example, by a computer 2a. The processor 2a1 may be configured to read a program from the storage 2a2 and perform various control operations by executing the read program. The program may be stored in advance in the storage 2a2, or may be acquired via a medium when necessary. The acquired program is stored in the storage 2a2, read from the storage 2a2 by the processor 2a1, and executed thereby. The medium may be any of various recording media readable by the computer 2a, or may be a communication line connected to the communication interface 2a3. The processor 2a1 may be a central processing unit (CPU). The storage 2a2 may include a random access memory (RAM), a read only memory (ROM), a hard disk drive (HDD), a solid state drive (SSD), or a combination thereof. The communication interface 2a3 may communicate with the plasma processing apparatus 1 via a communication line such as a local area network (LAN). The functionality of the elements disclosed herein may be implemented using circuitry or processing circuitry which includes general purpose processors, special purpose processors, integrated circuits, ASICs (“Application Specific Integrated Circuits”), FPGAs (“Field-Programmable Gate Arrays”), conventional circuitry and/or combinations thereof which are programmed, using one or more programs stored in one or more memories, or otherwise configured to perform the disclosed functionality. Processors and controllers are considered processing circuitry or circuitry as they include transistors and other circuitry therein. In the disclosure, the circuitry, units, or means are hardware that carry out or are programmed to perform the recited functionality. The hardware may be any hardware disclosed herein which is programmed or configured to carry out the recited functionality. There is a memory that stores a computer program which includes computer instructions. These computer instructions provide the logic and routines that enable the hardware (e.g., processing circuitry or circuitry) to perform the method disclosed herein. This computer program can be implemented in known formats as a computer-readable storage medium, a computer program product, a memory device, a record medium such as a CD-ROM or DVD, and/or the memory of a FPGA or ASIC.

Next, an operation of the plasma processing apparatus 1 in one or more embodiments will be described briefly.

The substrate W is loaded into the plasma processing chamber 10 through a loading and unloading port by a transfer mechanism such as a transfer arm, and placed on the substrate support 11. When the plasma processing is performed, the plasma processing apparatus 1 reduces, by the exhaust system 40, a pressure in the plasma processing chamber 10 to a predetermined vacuum suitable for the plasma processing. The plasma processing apparatus 1 supplies a processing gas from the gas supply 20 and introduces the processing gas through the shower head 13 into the plasma processing chamber 10. Then, the plasma processing apparatus 1 supplies at least one RF signal from the RF power supply 31 to generate a plasma in the plasma processing space 10s, and performs the plasma processing on the substrate W.

In one or more embodiments, the plasma processing apparatus 1 supplies a plurality of radio-frequency powers (RF signals) having different frequencies from the RF power supply 31 to the lower electrode provided on the base 1110 so as to generate plasma in the plasma processing chamber 10, and performs etching as the plasma processing. The first RF generator 31a is coupled to the lower electrode via the first impedance matching circuit 33a to supply the source RF signal. The second RF generator 31b is coupled to the lower electrode via the second impedance matching circuit 33b, and supplies the bias RF signal in a pulsed manner.

When output impedances of the first impedance matching circuit 33a and the second impedance matching circuit 33b are different from an input impedance on a load side (the plasma processing chamber 10 side), reflection or loss occurs in the source RF signal and the bias RF signal. Therefore, the first impedance matching circuit 33a matches an output impedance of the first RF generator 31a and the input impedance on the load side with each other. The second impedance matching circuit 33b matches an output impedance of the second RF generator 31b and the input impedance on the load side with each other.

Here, configurations of the first impedance matching circuit 33a and the second impedance matching circuit 33b will be described. Since the first impedance matching circuit 33a and the second impedance matching circuit 33b have the same configuration, the configuration of the second impedance matching circuit 33b will be described as an example.

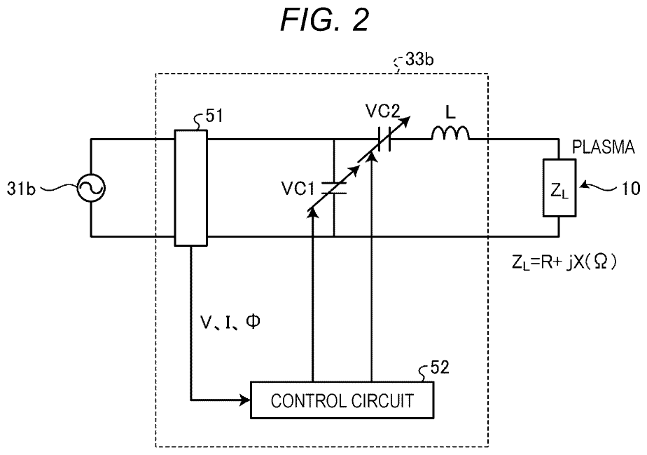

FIG. 2 is a schematic diagram illustrating an example of the second impedance matching circuit 33b according to one or more embodiments. The first impedance matching circuit 33a can have the same configuration as the second impedance matching circuit 33b. FIG. 2 is an equivalent circuit illustrating electric characteristics of a path through which the bias RF signal flows. In the equivalent circuit illustrated in FIG. 2, an impedance of the plasma generated in the plasma processing chamber 10 is illustrated as Z_{L}. The second impedance matching circuit 33b includes variable capacitors VC1 and VC2, an inductor L, a sensor 51, and a control circuit 52. The variable capacitor VC1 and the inductor L are connected in series with the plasma processing chamber 10. The variable capacitor VC2 is connected in parallel with the plasma processing chamber 10. The sensor 51 is provided closer to the second RF generator 31b than the variable capacitor VC1 and the inductor L. The sensor 51 detects a voltage V, a current I, and a phase difference p between the voltage V and the current I of the bias RF signal. The control circuit 52 calculates the output impedance of the second RF generator 31b based on the voltage V, the current I, the phase difference p between the voltage V and the current I, which are detected by the sensor 51. The control circuit 52 controls electrostatic capacitances of the variable capacitors VC1 and VC2 such that the output impedance of the second RF generator 31b and the input impedance on the load side match with each other. For example, when the output impedance is 50Ω, the control circuit 52 controls the electrostatic capacitances of the variable capacitors VC1 and VC2 such that the input impedance is 50Ω.

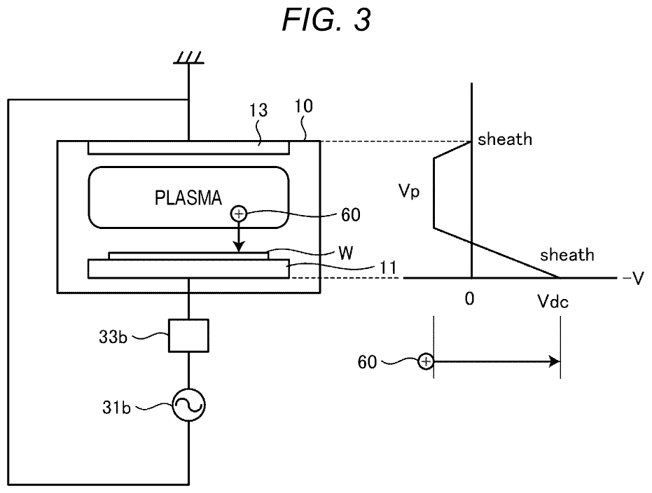

FIG. 3 is a diagram illustrating the plasma processing of the plasma processing apparatus 1 according to one or more embodiments. FIG. 3 schematically illustrates the plasma processing apparatus 1. When the source RF signal and the bias RF signal are applied to the lower electrode of the base 1110 constituting the substrate support 11, the plasma is formed in the plasma processing chamber 10. The right side of FIG. 3 illustrates a change in potential according to a position between the shower head 13 and the substrate support 11 in the plasma processing chamber 10. The plasma has a positive potential Vp. The shower head 13 has a potential of 0, and the substrate support 11 has a negative potential Vdc. Positive ions 60 in the plasma are accelerated toward the substrate W by a potential difference between the potential Vp and the potential Vdc. The substrate W is etched by incidence of the accelerated positive ions 60.

An impedance of the plasma processing apparatus 1 during the plasma processing is determined by various variables including a type of a process gas, a temperature, a pressure, and the bias RF signal, and thus changes to various values. Accordingly, in the plasma processing apparatus 1, the input impedance on the load side (the plasma processing chamber 10 side) changes. In particular, when the bias RF signal is supplied in a pulsed manner, the potential Vdc of the substrate support 11 changes according to a cycle of the bias RF signal, and the impedance changes in a short time. For example, when the second RF generator 31b turns on/off the bias RF signal in a cycle of several hundred kHz to 1 MHz to perform pulse modulation, the impedance changes in units of microseconds. In one or more embodiments, in order to improve the matching speed of the first impedance matching circuit 33a and the second impedance matching circuit 33b, the variable capacitors VC1 and VC2 are configured as follows.

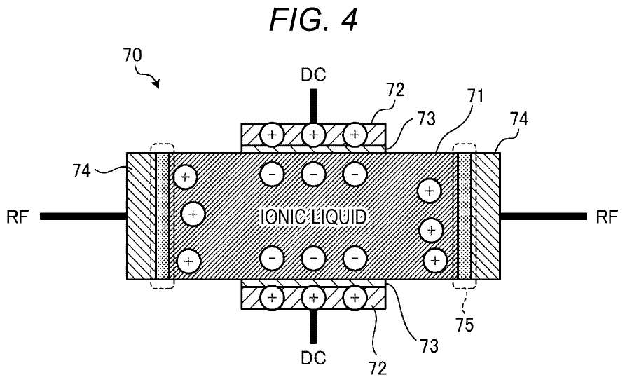

FIG. 4 is a diagram schematically illustrating an example of a configuration of a variable capacitor 70 according to one or more embodiments. The variable capacitor 70 includes a holder 71 (i.e., enclosure) configured to hold an ionic liquid. The ionic liquid is an ionic compound that is a liquid at a room temperature containing cations and anions, and is also referred to as a room temperature molten salt. The ionic liquid has characteristics, such as almost zero vapor pressure and non-volatility (e.g., does not volatilize even at a high temperature or in a vacuum). In addition, the ionic liquid has a potential window wider than that of an aqueous solution or an organic solvent, and can be used as an electrolyte in a state where these are not contained. The details of the ionic liquid, including its material composition, will be described later.

The holder 71 may be an airtight container that stores the ionic liquid that is a liquid, and may comprise an absorbent material, such as electrolytic paper that can absorb and hold the ionic liquid. The holder 71 may be configured to hold the ionic liquid in a gel state or alternatively, in a liquid state.

In FIG. 4, the holder 71 is formed in a rectangular shape. However, the holder 71 can have any shape and is not restricted to only a rectangular shape. The holder 71 is provided with DC electrodes 72 facing each other in an up-down direction. The DC electrodes 72 are in contact with the holder 71 via dielectrics 73. Dielectrics 73 are as known in the art, and are an electrical insulator (e.g., a non-conducting material) that can be polarized by an applied electric field, allowing it to store electrical energy. The holder 71 is provided with RF electrodes 74 facing each other in a left-right direction. The DC electrodes 72 and the RF electrodes 74 are formed of a conductive metal. In one or more embodiments, the DC electrode 72 corresponds to the first electrode of the disclosure, and the RF electrode 74 corresponds to the second electrode of the disclosure.

Either the positive or negative direct-current voltage is applied to the DC electrode 72. When the direct-current voltage is applied to the DC electrode 72 with reference to the RF electrode 74, an electrostatic field is formed through the dielectric 73 in the holder 71. Electric double layers 75 are formed in the ionic liquid held by the holder 71. For example, when a positive direct-current voltage is applied to the DC electrodes 72, in the holder 71, the anions in the ionic liquid collect in the vicinity of the DC electrodes 72 by an electric field caused by the direct-current voltage, and the cations collect in the left and right sides to form the electric double layers 75 in the left and right sides. The RF electrodes 74 are provided on portions of the holder 71 where the electric double layers in the ionic liquid 75 are formed when the direct-current voltage is applied to the DC electrodes 72. The electric double layer 75 functions as a capacitor. In the variable capacitor 70, when the radio-frequency power is supplied to the RF electrode 74 on one side, the radio-frequency power is supplied to the RF electrode 74 on the other side via the holder 71.

When the direct-current voltage applied to the DC electrode 72 changes, an amount (density) of ions collected in the electric double layer 75 changes, and an electrostatic capacitance of the variable capacitor 70 changes. Since the ionic liquid does not contain an aqueous solution and an organic solvent, a higher voltage can be applied, so that the electrostatic capacitance can be increased. Therefore, a value of the electrostatic capacitance can be changed over a wider range. Since the electrostatic capacitance changes due to the movement of ions in the ionic liquid held in the holder 71, the electrostatic capacitance of the variable capacitor 70 quickly changes. Accordingly, the variable capacitor 70 can continuously and quickly control the electrostatic capacitance by controlling the direct-current voltage that is applied to the DC electrode 72. For example, the variable capacitor 70 can continuously change the electrostatic capacitance in units of microseconds according to the change in the direct-current voltage applied to the DC electrode 72. The impedance of the plasma processing apparatus 1 is determined by various variables including the type of the process gas, the temperature, the pressure, and the bias RF signal, and thus changes to various values. In order to cope with such a change in impedance using a common capacitor, it is necessary to prepare a plurality of capacitors having different amounts of electrostatic capacitances and combine these capacitors. However, since the variable capacitor 70 can continuously change the electrostatic capacitance by the direct-current voltage applied to the DC electrode 72, the variable capacitor 70 can also cope with changes in various impedances of the plasma processing apparatus 1.

The first impedance matching circuit 33a and the second impedance matching circuit 33b can improve the matching speed by using the variable capacitors 70 for the variable capacitors VC1 and VC2. For example, in the second impedance matching circuit 33b, the control circuit 52 controls the direct-current voltage applied to the DC electrode 72 such that the output impedance of the second RF generator 31b and the input impedance on the load side match with each other, according to a cycle of the pulse modulation of the bias RF signal. For example, the control circuit 52 controls the direct-current voltage applied to the DC electrode 72 such that the output impedance of the second RF generator 31b and the input impedance of the load match with each other in the cycle of the pulse modulation of the bias RF signal or a cycle shorter than the cycle of the pulse modulation. Accordingly, the first impedance matching circuit 33a and the second impedance matching circuit 33b can perform the pulse modulation on the bias RF signal to match the impedances even when the input impedance on the load side changes in units of microseconds.

The control circuit 52 may hold (e.g., store in memory of the control circuit 52) a look-up table based on pre-verification, and control the electrostatic capacitances of the variable capacitors VC1 and VC2 using the look-up table. The look-up table includes the electrostatic capacitance to be attained by each of the variable capacitors VC1 and VC2 when the input impedance and the output impedance match with each other, and the value of the direct-current voltage applied to the DC electrode 72 necessary for obtaining the electrostatic capacitances thereof, with respect to the respective values of the input impedance and the output impedance. Accordingly, the control circuit 52 can quickly determine the value of the direct-current voltage to be applied to the DC electrode 72 corresponding to the detected input impedance and output impedance with reference to the look-up table, and apply the direct-current voltage.

### [Ionic Liquid]

Next, the ionic liquid will be described. As described above, the ionic liquid contains cations and anions.

Examples of the cations constituting the ionic liquid include quaternary nitrogen-containing cations such as a pyridinium-type, an imidazolium-type, an ammonium-type, a pyrrolidinium-type, and a piperidinium-type, and quaternary phosphorus-containing cations such as a phosphonium-type. These cations contain an alkyl group —(CH₂)ₙCH₃ as a side chain.

Examples of the pyridinium-type cations include, but are not limited to, C₂py⁺ represented by chemical formula (C1-1) and C₄py⁺ represented by chemical formula (C1-2).

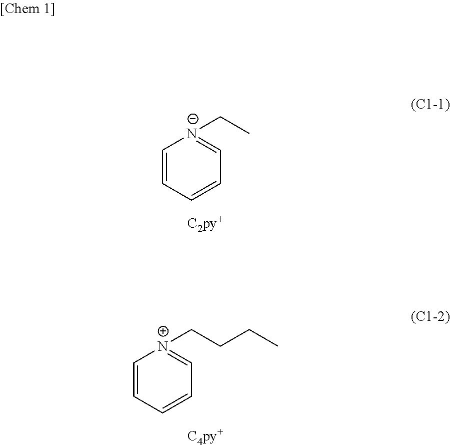

Examples of the imidazolium-type cations include, but are not limited to, C₂mim⁺ represented by chemical formula (C2-1), C₄mim⁺ represented by chemical formula (C2-2), C₆mim⁺ represented by chemical formula (C2-3), C₈mim⁺ represented by chemical formula (C2-4), and emim (1-ethyl-3-methylimidazolium) represented by chemical formula (C2-5).

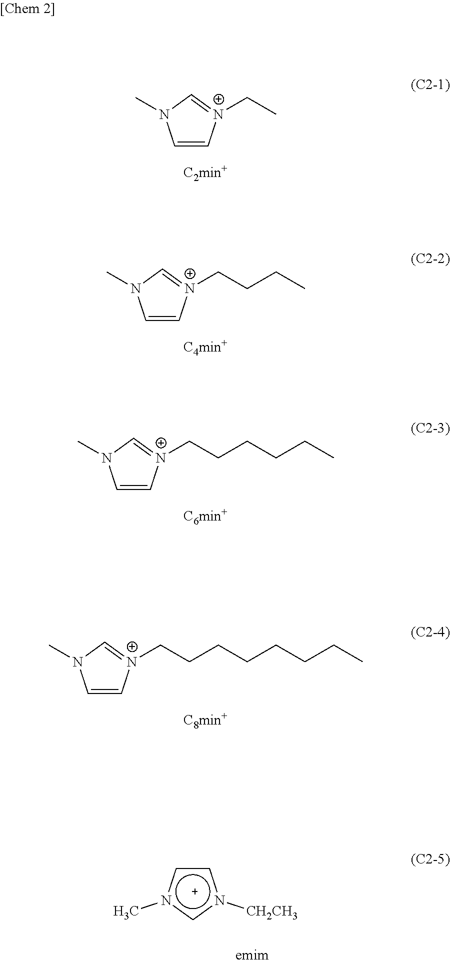

Examples of the ammonium-type cations include, but are not limited to, N_{3,1,1,1}⁺ represented by chemical formula (C3-1), N_{4,1,1,1}⁺ represented by chemical formula (C3-2), N_{6,1,1,1}⁺ represented by chemical formula (C3-3), N_{2,2,1,(2O1)}⁺ represented by chemical formula (C3-4), and Ch⁺ represented by chemical formula (C3-5).

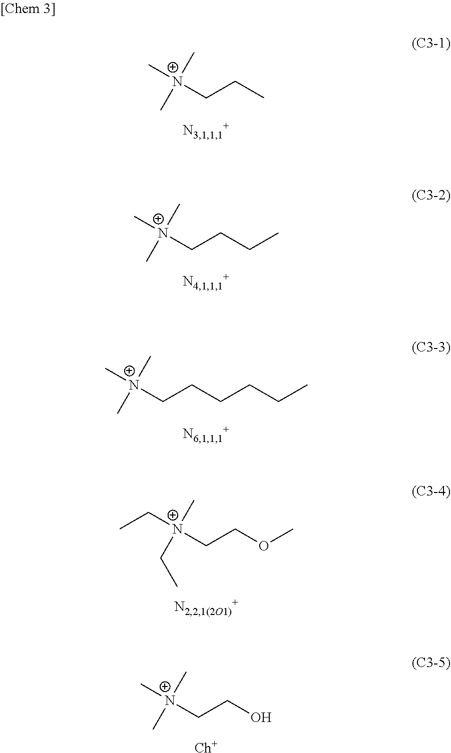

Examples of the pyrrolidinium-type cations include, but are not limited to, Pyr_{1,3}⁺ represented by chemical formula (C4-1) and Pyr_{1,4}⁺ represented by chemical formula (C4-2).

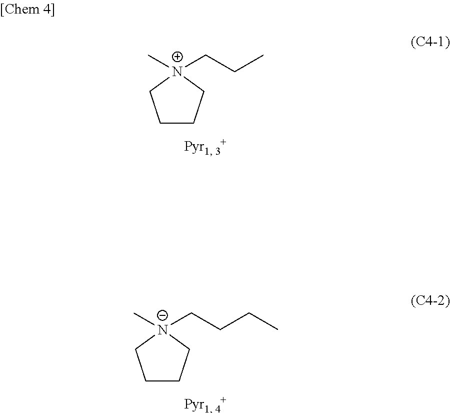

Examples of the piperidinium-type cations include, but are not limited to, Pip_{1,3}⁺ represented by chemical formula (C5-1) and Pip_{1,4}⁺ represented by chemical formula (C5-2).

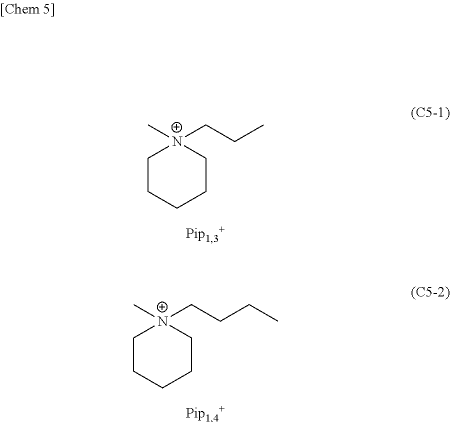

Examples of the phosphonium-type cations include, but are not limited to, P_{5,2,2,2}⁺ represented by chemical formula (C6-1) and P_{6,6,6,14}⁺ represented by chemical formula (C6-2).

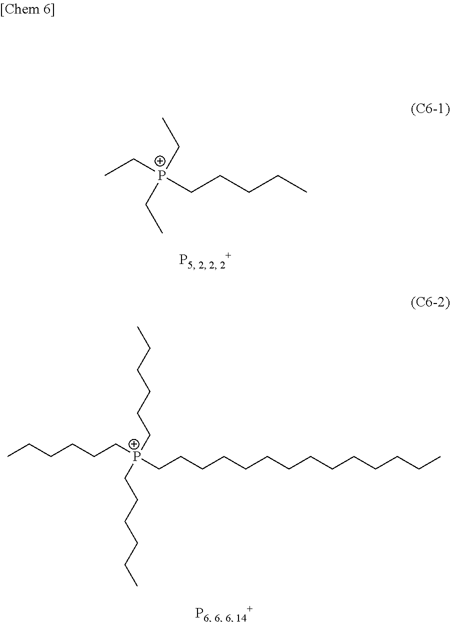 [SMILES: CCCCC[P+](CC)(CC)CC ; CCCCCCCCCCCCCC[P+](CCCCCC)(CCCCCC)CCCCCC]

Examples of the anions constituting the ionic liquid include, but are not limited to, TfO⁻ represented by chemical formula (A1), Tf₂N⁻ (TFSA⁻) represented by chemical formula (A2), Tf₃C⁻ represented by chemical formula (A3), FSA⁻ represented by chemical formula (A4), CH₃COO⁻ represented by chemical formula (A5), CF₃COO⁻ represented by chemical formula (A6), BF₄⁻ represented by chemical formula (A7), PF₆⁻ represented by chemical formula (A8), (CN)₂N⁻(DCA⁻) represented by chemical formula (A9), AlCl₄⁻ represented by chemical formula (A10), Al₂Cl₇⁻ represented by chemical formula (A11), and BETI⁻ represented by chemical formula (A12).

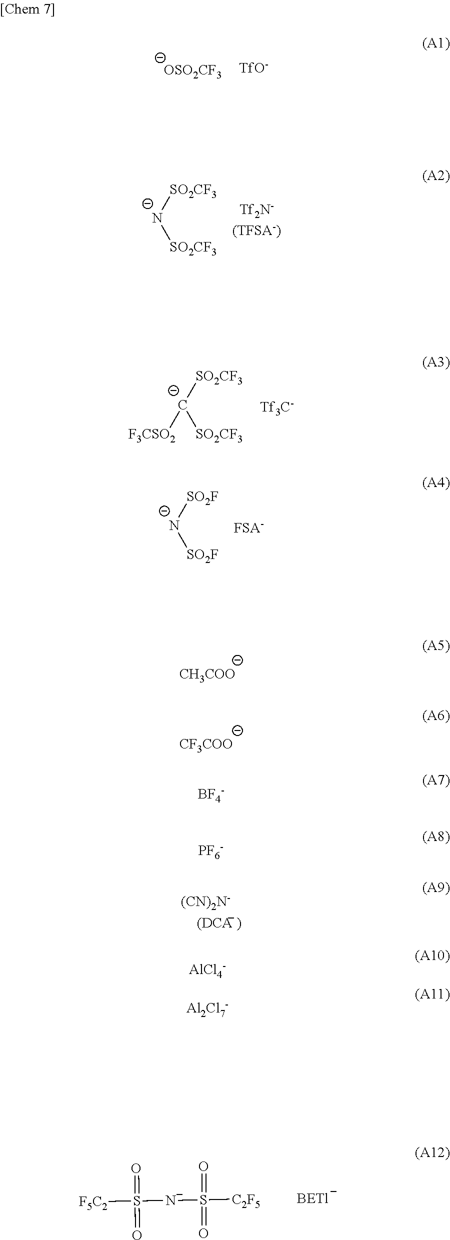

In order to speed up the response of the electrostatic capacitance of the variable capacitor 70, it is preferable that the ionic liquid contains cations as emim. In the ionic liquid, it is preferable that the anions are any one of FSA⁻, TFSA⁻, BETI⁻, DCA⁻, and BF₄⁻. Specific examples of the combination of cations and anions in the ionic liquid include emim and FSA, emim and TFSA, emim and BETI, emim and DCA, and emim and BF₄⁻. As the combination of cations and anions in the ionic liquid, emim and DCA is particularly preferable.

### (Specific Configuration of Variable Capacitor 70)

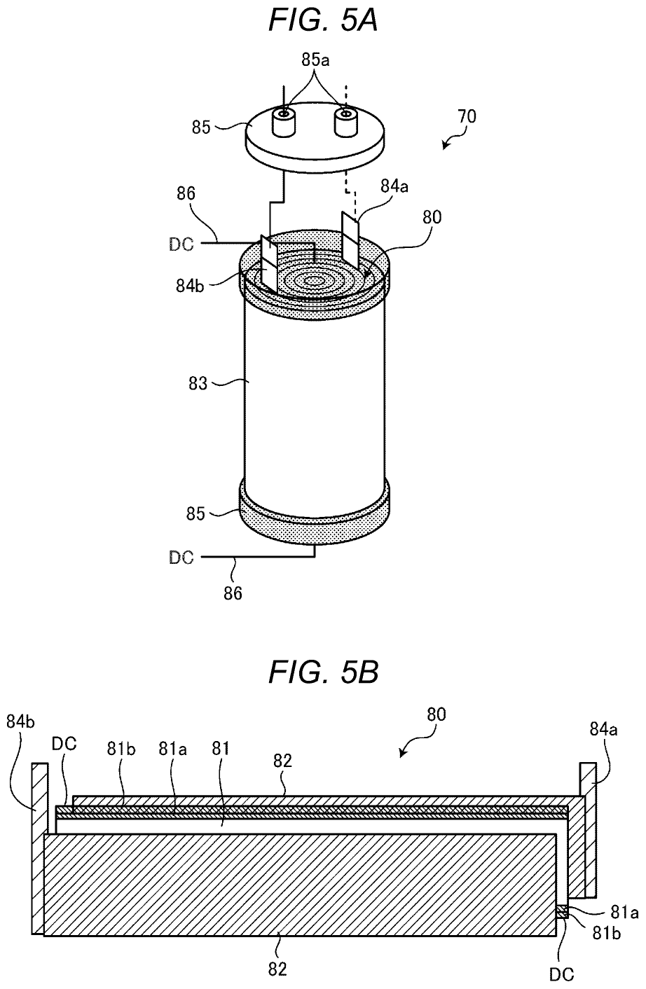

Next, a specific example of the configuration of the variable capacitor 70 will be described. FIGS. 5A and 5B are diagrams illustrating a specific example of the configuration of the variable capacitor 70 according to one or more embodiments. FIGS. 5A and 5B illustrate a cylindrical variable capacitor 70. FIG. 5A illustrates the configuration of the variable capacitor 70. The variable capacitor 70 includes at least a roll member 80 and a cylindrical case 83.

FIG. 5B illustrates a configuration of the roll member 80. The roll member 80 is implemented by a separator 81 and two electrodes 82 having the same size as the separator 81. The separator 81 corresponds to the holder 71, and the electrode 82 corresponds to the RF electrode 74. The separator 81 absorbs and holds the ionic liquid. The separator 81 is provided with electrodes 81b via dielectrics 81a at both ends in a short side direction. A current collection terminal 84a is connected to one end portion of one electrode 82 of the two electrodes 82 in a long side direction. A current collection terminal 84b is connected to the other end portion of the other electrode 82 in the long side direction and the other end portion is disposed at an opposing end from the one end portion. The one end portion may be designated as a first end portion, and the other end portion may be designated as a second end portion. Both bottom surfaces (e.g., end surfaces) of the case 83 are sealed by sealing plates 85. The roll member 80 is wound in a roll shape in a state where the electrodes 82 are laminated on both surfaces of the separator 81, and is accommodated in the case 83. One sealing plate 85 has two through-holes 85a. The current collection terminals 84a and 84b are led to the outside through the through-holes 85a, respectively. In the variable capacitor 70, wirings 86 are provided on both the bottom surfaces of the case 83. The wirings 86 are respectively connected to the electrodes 81b in the short side direction on the separator 81.

In the variable capacitor 70 illustrated in FIGS. 5A and 5B, a direct-current voltage is applied to the electrodes 81b via the wirings 86, whereby the direct-current voltage is applied to the ionic liquid absorbed by the separator 81, and an electric double layer is formed on the surface side in contact with the electrode 82. The variable capacitor 70 supplies a radio-frequency power between the current collection terminal 84a and the current collection terminal 84b. In the variable capacitor 70, when the direct-current voltage applied to the wiring 86 changes, the electrostatic capacitance changes. Since the electrostatic capacitance of the variable capacitor 70 changes due to the movement of ions in the ionic liquid, the electrostatic capacitance quickly changes. Accordingly, by controlling the direct-current voltage applied to the wiring 86, the variable capacitor 70 can continuously and quickly control the electrostatic capacitance.

FIGS. 4, 5A, and 5B are diagrams illustrating an example of the configuration of the variable capacitor 70. The configuration of the variable capacitor 70 is not limited to FIGS. 4, 5A, and 5B. For example, one or three or more DC electrodes 72 may be provided as long as the electric double layer 75 can be formed on the ionic liquid held in the holder 71. The RF electrode 74 may be provided in any portion of the holder 71 as long as the radio-frequency power can be supplied via the holder 71.

In the above embodiment, a case where the plasma processing is performed by supplying the plurality of radio-frequency powers from the RF power supply 31 to the lower electrode provided on the base 1110 has been described as an example. However, the technique disclosed herein is not limited thereto. The plasma processing apparatus 1 may perform the plasma processing by supplying the radio-frequency power from the RF power supply 31 to the upper electrode provided on the shower head 13. The plasma processing apparatus 1 may perform the plasma processing by supplying the radio-frequency power from the RF power supply 31 to the lower electrode of the base 1110 and the upper electrode of the shower head 13, respectively.

In the above embodiment, a case where the plasma processing apparatus 1 performs etching as the plasma processing has been described as an example. However, the technique disclosed herein is not limited thereto. The plasma processing apparatus 1 may perform film formation, ashing, modification, or the like as the plasma processing.

It shall be understood that the embodiments disclosed herein are illustrative and are not restrictive in all aspects. Indeed, the above-described embodiment can be implemented in various forms. The embodiment described above may be omitted, replaced, or modified in various forms without departing from the scope and spirit of the appended claims. The present disclosure encompasses various modifications to each of the examples and embodiments discussed herein. According to the disclosure, one or more features described above in one embodiment or example can be equally applied to another embodiment or example described above. The features of one or more embodiments or examples described above can be combined into each of the embodiments or examples described above. Any full or partial combination of one or more embodiment or examples of the disclosure is also part of the disclosure.

Further, the following appendixes will be further disclosed with respect to the above-described embodiment.

### APPENDIX 1

A variable capacitor including:
a holder configured to hold an ionic liquid;
at least one first electrode provided on the holder and configured to receive either a positive or negative direct-current voltage; and
at least two second electrodes provided on portions of the holder where electric double layers in the ionic liquid are formed when the direct-current voltage is applied to the first electrode, and configured to supply a radio-frequency power via the holder.

### APPENDIX 2

The variable capacitor according to Appendix 1, in which
two first electrodes are provided to face each other with the holder interposed therebetween.

### APPENDIX 3

The variable capacitor according to Appendix 2, in which
the second electrodes are disposed to face each other with the holder interposed therebetween in a cross direction (e.g., orthogonal direction) with respect to a direction in which the two first electrodes face each other. Alternatively, the second electrodes can face each other in a first direction that is different to a second direction in which the two first electrodes face each other, where the first direction is not orthogonal to the second direction.

### APPENDIX 4

The variable capacitor according to any one of Appendices 1 to 3, in which
cations of the ionic liquid are emim represented by chemical formula (C2-5).

### APPENDIX 5

The variable capacitor according to Appendix 4, in which
anions of the ionic liquid are any one of FSA⁻ represented by chemical formula (A4), TFSA⁻ represented by chemical formula (A2), BETI⁻ represented by chemical formula (A12), DCA⁻ represented by chemical formula (A9), and BF₄⁻.

### APPENDIX 6

The variable capacitor according to any one of Appendices 1 to 5, in which
the holder is configured to hold the ionic liquid in a liquid state or in a state where the ionic liquid is absorbed by an absorbent material or in a gel state.

### APPENDIX 7

The variable capacitor according to any one of Appendices 1 to 6, in which
the first electrode is formed of a conductive metal, and is configured to come into contact with the holder via a dielectric, and
the second electrode is formed of a conductive metal.

### APPENDIX 8

An impedance matching apparatus including:
an impedance matching circuit including the variable capacitor according to any one of Appendices 1 to 7 and provided between a radio-frequency power supply and a load; and
a control circuit configured to control the direct-current voltage that is applied to the first electrode of the variable capacitor such that impedances of the radio-frequency power supply and the load match with each other.

### APPENDIX 9

The impedance matching apparatus according to Appendix 8, in which
the control circuit holds a look-up table in which a value of the direct-current voltage to be applied to the first electrode of the variable capacitor when the impedances of the radio-frequency power supply and the load match with each other with respect to respective values of the impedances of the radio-frequency power supply and the load are stored, and controls the direct-current voltage to be applied to the first electrode with reference to the look-up table.

### APPENDIX 10

A plasma processing apparatus including:
a chamber in which an electrode is provided;
a radio-frequency power supply configured to supply a radio-frequency power to the electrode; and
the impedance matching apparatus according to Appendix 8 or 9 that is provided between the radio-frequency power supply and the chamber, and that matches impedances of the radio-frequency power supply and the chamber with each other.

### APPENDIX 11

The plasma processing apparatus according to Appendix 10, in which
the radio-frequency power supply supplies a plurality of radio-frequency powers having different frequencies including a pulse-modulated radio-frequency power, to the electrode, and
the impedance matching apparatus matches the impedances of the radio-frequency power supply and the chamber with each other according to a cycle of the pulse modulation.

### APPENDIX 12

A plasma processing apparatus, comprising:
a plasma processing chamber defining a plasma processing space;
a substrate support disposed in the plasma processing chamber and including at least one lower electrode;
a radio-frequency power supply to supply radio-frequency power to the at least one lower electrode;
an impedance matching apparatus coupled between the radio-frequency power supply and the at least one lower electrode,
the impedance matching apparatus including a variable capacitor having:
a holder that holds an ionic liquid;
at least one first electrode in the holder that receives a direct-current voltage to form electric double layers in the ionic liquid, and
at least two second electrodes on portions of the holder where the electric double layers form to supply the radio-frequency power; and
a control circuit configured to adjust the direct-current voltage to continuously control an electrostatic capacitance of the variable capacitor for impedance matching.

### APPENDIX 13

The plasma processing apparatus according to Appendix 12, wherein
the at least one first electrode includes two first electrodes, and
the two first electrodes are provided to face each other with the holder interposed therebetween.

### APPENDIX 14

The plasma processing apparatus according to Appendix 13, wherein
the second electrodes face each other with the holder interposed therebetween in a direction orthogonal with respect to a direction in which the two first electrodes face each other.

### APPENDIX 15

The plasma processing apparatus according to Appendix 12, wherein
cations of the ionic liquid are emim represented by chemical formula (1).

### [Chem 1]

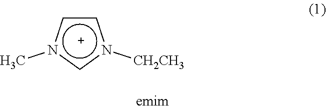

### APPENDIX 16

The plasma processing apparatus according to Appendix 15, wherein
anions of the ionic liquid are any one of FSA− represented by chemical formula (2), TFSA− represented by chemical formula (3), BETI− represented by chemical formula (4), DCA− represented by chemical formula (5), and BF4-.

### [Chem 2]

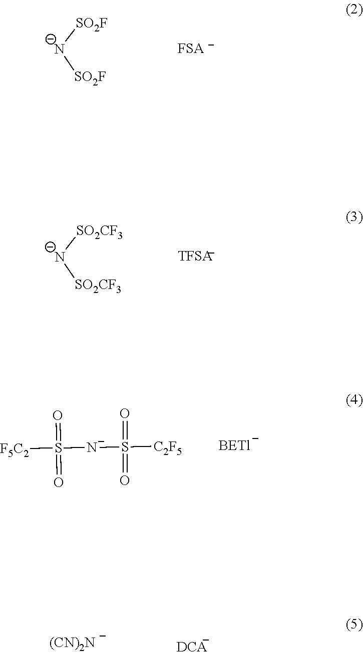

### APPENDIX 17

The plasma processing apparatus according to Appendix 12, wherein
the holder holds the ionic liquid in a liquid state, in a state where the ionic liquid is absorbed by an absorbent material, or in a gel state.

### APPENDIX 18

The plasma processing apparatus according to Appendix 12, wherein
the control circuit includes memory that stores a look-up table, the look-up table storing electrostatic capacitance of the variable capacitor and the direct-current voltage to be applied to the at least one first electrode of the variable capacitor to achieve the capacitance when the impedances of the radio-frequency power supply and the load match with each other, and the control circuit is further configured to control the direct-current voltage to be applied to the at least one first electrode with reference to the look-up table.

### APPENDIX 19

A non-transitory computer-readable medium storing instructions that, when executed by a processor of a control circuit in an impedance matching apparatus, cause the processor to:
apply a direct-current voltage to at least one first electrode in a holder containing an ionic liquid to form electric double layers;
supply radio-frequency power via at least two second electrodes on portions of the holder where the electric double layers form;
monitor impedances between a radio-frequency power supply and a load; and
vary the direct-current voltage based on a look-up table to match the impedances by adjusting an electrostatic capacitance of a variable capacitor.

### APPENDIX 20

The non-transitory computer-readable medium according to Appendix 19, wherein the instructions further cause the processor to use a sensor to detect reflected power for monitoring the impedances.

### REFERENCE SIGNS LIST

1: plasma processing apparatus
10: plasma processing chamber
11: substrate support
13: shower head
30: power supply
31: RF power supply
31a: first RF generator
31b: second RF generator
32: power supply
32a: first DC generator
32b: second DC generator
33: impedance matching circuit
33a: first impedance matching circuit
33b: second impedance matching circuit
40: exhaust system
51: sensor
52: control circuit
60: ion
70: variable capacitor
71: holder
73: dielectric
75: electric double layer
80: roll member
81: separator
81a: dielectric
81b: electrode
82: electrode
83: case
84a: current collection terminal
84b: current collection terminal
85: sealing plate
86: wiring
85a: through-hole
86: wiring
111: main body
112: ring assembly
1110: base
1111: electrostatic chuck
L: inductor
RF: bias
RF: source
VC1: variable capacitor
VC2: variable capacitor
W: substrate

1. A variable capacitor, comprising:
a holder to hold an ionic liquid;
at least one first electrode provided on the holder, the at least one first electrode receiving either a positive or negative direct-current voltage; and
at least two second electrodes provided on portions of the holder where electric double layers in the ionic liquid are formed when the direct-current voltage is applied to the first electrode, the at least two second electrodes configured to supply a radio-frequency power via the holder.

2. The variable capacitor according to claim 1, wherein
the at least one first electrode includes two first electrodes, and
the two first electrodes are provided to face each other with the holder interposed therebetween.

3. The variable capacitor according to claim 2, wherein
the second electrodes face each other with the holder interposed therebetween in a direction orthogonal with respect to a direction in which the two first electrodes face each other.

4. The variable capacitor according to claim 1, wherein
cations of the ionic liquid are emim represented by chemical formula (1).
[Chem 1]

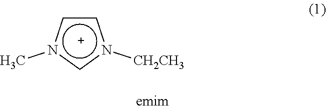

5. The variable capacitor according to claim 4, wherein
anions of the ionic liquid are any one of FSA⁻ represented by chemical formula (2), TFSA⁻ represented by chemical formula (3), BETI⁻ represented by chemical formula (4), DCA⁻ represented by chemical formula (5), and BF₄⁻.
[Chem 2]

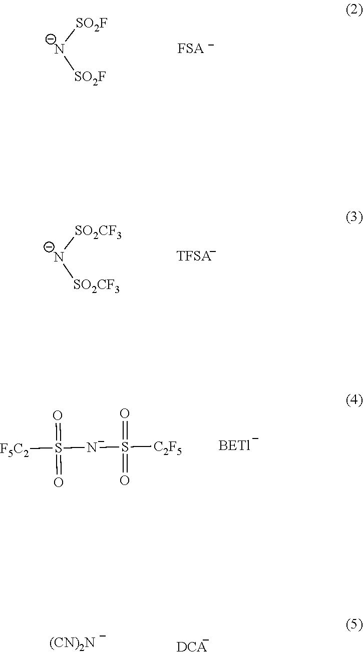

6. The variable capacitor according to claim 1, wherein
the holder holds the ionic liquid in a liquid state, in a state where the ionic liquid is absorbed by an absorbent material, or in a gel state.

7. The variable capacitor according to claim 1, wherein
each of the at least one first electrode is formed of a conductive metal, and comes into contact with the holder via a dielectric, and
each of the at least two second electrodes is formed of a conductive metal.

8. An impedance matching apparatus, comprising:
an impedance matching circuit including the variable capacitor according to claim 1 and provided between a radio-frequency power supply and a load; and
a control circuit configured to control the direct-current voltage that is applied to the at least one first electrode of the variable capacitor such that impedances of the radio-frequency power supply and the load match with each other.

9. The impedance matching apparatus according to claim 8, wherein
the control circuit includes memory that stores a look-up table, the look-up table storing electrostatic capacitance of the variable capacitor and the direct-current voltage to be applied to the at least one first electrode of the variable capacitor to achieve the capacitance when the impedances of the radio-frequency power supply and the load match with each other, and
the control circuit is further configured to control the direct-current voltage to be applied to the at least one first electrode with reference to the look-up table.

10. A plasma processing apparatus, comprising:
a chamber in which an electrode is provided;
a radio-frequency power supply to supply a radio-frequency power to the electrode; and
the impedance matching apparatus according to claim 8 that is provided between the radio-frequency power supply and the chamber, the impedance matching apparatus matching impedances of the radio-frequency power supply and the chamber with each other.

11. The plasma processing apparatus according to claim 10, wherein
the radio-frequency power supply supplies a plurality of radio-frequency powers having different frequencies including a pulse-modulated radio-frequency power to the electrode, and
the impedance matching apparatus matches the impedances of the radio-frequency power supply and the chamber with each other according to a cycle of the pulse modulation.

12. A plasma processing apparatus, comprising:
a plasma processing chamber defining a plasma processing space;
a substrate support disposed in the plasma processing chamber and including at least one lower electrode;
a radio-frequency power supply to supply radio-frequency power to the at least one lower electrode;
an impedance matching apparatus coupled between the radio-frequency power supply and the at least one lower electrode,
the impedance matching apparatus including a variable capacitor having:
a holder that holds an ionic liquid;
at least one first electrode in the holder that receives a direct-current voltage to form electric double layers in the ionic liquid, and
at least two second electrodes on portions of the holder where the electric double layers form to supply the radio-frequency power; and
a control circuit configured to control the radio-frequency power supply to adjust the direct-current voltage to continuously control an electrostatic capacitance of the variable capacitor for impedance matching.

13. The plasma processing apparatus according to claim 12, wherein
the at least one first electrode includes two first electrodes, and
the two first electrodes are provided to face each other with the holder interposed therebetween.

14. The plasma processing apparatus according to claim 13, wherein
the at least two second electrodes face each other with the holder interposed therebetween in a direction orthogonal with respect to a direction in which the two first electrodes face each other.

15. The plasma processing apparatus according to claim 12, wherein
cations of the ionic liquid are emim represented by chemical formula (1).

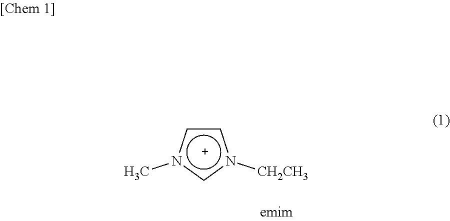

16. The plasma processing apparatus according to claim 15, wherein
anions of the ionic liquid are any one of FSA⁻ represented by chemical formula (2), TFSA⁻ represented by chemical formula (3), BETI⁻ represented by chemical formula (4), DCA⁻ re resented by chemical formula (5), and BF₄⁻.

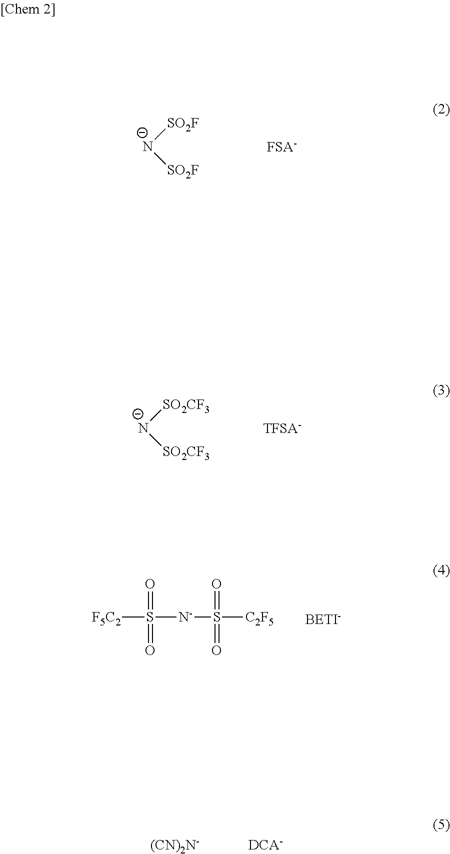

17. The plasma processing apparatus according to claim 12, wherein
the holder holds the ionic liquid in a liquid state, in a state where the ionic liquid is absorbed by an absorbent material, or in a gel state.

18. The plasma processing apparatus according to claim 12, wherein
the control circuit includes memory that stores a look-up table, the look-up table storing electrostatic capacitance of the variable capacitor and the direct-current voltage to be applied to the at least one first electrode of the variable capacitor to achieve the capacitance when the impedances of the radio-frequency power supply and the load match with each other, and
the control circuit is further configured to control the direct-current voltage to be applied to the at least one first electrode with reference to the look-up table.

19. A non-transitory computer-readable medium storing instructions that, when executed by a processor of a control circuit in an impedance matching apparatus, cause the processor to:
apply a direct-current voltage to at least one first electrode in a holder containing an ionic liquid to form electric double layers;
supply radio-frequency power via at least two second electrodes on portions of the holder where the electric double layers form;
monitor impedances between a radio-frequency power supply and a load; and
vary the direct-current voltage based on a look-up table to match the impedances by adjusting an electrostatic capacitance of a variable capacitor.

20. The non-transitory computer-readable medium according to claim 19, wherein the instructions further cause the processor to use a sensor to detect reflected power for monitoring the impedances.
